(19) United States
(12) Patent Application Publication
(10) Pub. No.: US 2026/0352206 A1
(43) Pub. Date: Nov. 5, 2026

(54) HIGH-SIDE SWITCH OVERLOAD DETECTION

(71) Applicant: Texas Instruments Incorporated, Dallas, TX (US)

(72) Inventors: Abdullah AL-OBAIDI, Carrollton, TX (US); Yichi ZHANG, Allen, TX (US)

(73) Assignee: Texas Instruments Incorporated, Dallas, TX (US)

(21) Appl. No.: 19/195,242

(22) Filed: Apr. 30, 2025

(51) Int. Cl. H03K 17/687; H02H 5/04; H03K 3/037

(52) U.S. Cl. CPC H03K 17/687; H02H 5/04; H03K 3/037; H03K 2217/0063

(57) ABSTRACT

An apparatus includes a transistor and a controller. The transistor has a first terminal, a second terminal, and a control terminal. The controller has an output coupled to the control terminal of the transistor, and an input coupled to the second terminal of the transistor. The controller is capable of turning the transistor on responsive to an enable signal. The controller is also capable of comparing a voltage at the input of the controller to a threshold. The controller is further capable of, responsive to a result of the comparing, either latching the transistor off or turning the transistor off for a time and then turning the transistor back on.

### BACKGROUND

A high-side switch circuit may be connected between a power supply and a load circuit to control provision of power to the load circuit. A switching device (or switch) in a high-side switch circuit may be a relay or a semiconductor switching device, such as a transistor. Semiconductors provide a number of advantages over electro-mechanical switches in high-side switching applications. For example, semiconductor switches may reduce the risk of electric spark, reduce circuit area, and reduce cost relative to electro-mechanical switches.

### SUMMARY

In one example, an apparatus includes a transistor and a controller. The transistor has a first terminal, a second terminal, and a control terminal. The controller has an output coupled to the control terminal of the transistor, and an input coupled to the second terminal of the transistor. The controller is capable of turning the transistor on responsive to an enable signal. The controller is also capable of comparing a voltage at the input of the controller to a threshold. The controller is further capable of, responsive to a result of the comparing, either latching the transistor off or turning the transistor off for a time and then turning the transistor back on.

In another example, a circuit includes a switch, temperature sensor circuitry, a comparator, logic circuitry, and a switch control circuit. The switch has a control input and a terminal. The temperature sensor circuitry has an output. The comparator has a first input coupled to the terminal of the switch, a reference input, and an output. The logic circuitry has an input coupled to the output of the comparator, and an output. The switch control circuit has a first input coupled to the output of the temperature sensor circuitry, a second input coupled to the output of the logic circuitry, and an output coupled to the control input of the switch.

In a further example, a system includes a battery, a load circuit, a processor, and a switch circuit. The battery has a terminal. The load circuit has an input. The processor has an output. The switch circuit includes a temperature sensor, a transistor, and a controller. The temperature sensor has an output. The transistor has a first terminal coupled to the terminal of the battery, a second terminal coupled to the input of the load circuit, and a control terminal. The controller includes a comparator, and circuitry. The comparator has a first input coupled to the second terminal of the transistor, a second input, and an output. The comparator is capable of providing an output signal responsive to comparing a voltage at its input to a reference voltage at its second input. The circuitry has a first input coupled to the output of the processor, a second input coupled to the output of the comparator, and an output coupled to the control terminal of the transistor. The circuitry of the controller capable of turning on the transistor responsive to a first enable signal at the output of the processor, and turning off the transistor responsive to a signal at the output of the temperature sensor. The controller is also capable of either latching the transistor off or turning the transistor off for a time and turning the transistor back on responsive the output signal from the comparator.

### BRIEF DESCRIPTION OF THE DRAWINGS

FIG. 1 is a block diagram of an example system that include a high-side switch circuit.

FIG. 2 is a block diagram of an example high-side switch circuit that controls switch closure based on overload severity.

FIG. 3 is a flow diagram of an example method of controlling a switching device in a high-side switch circuit.

FIG. 4 is a schematic diagram of an example of the high-side switch circuit of FIG. 2 showing example internal circuitry.

FIG. 5 is a flow diagram of an example method of controlling switch closure in a high-side switch circuit based on overload severity.

FIGS. 6 and 7 are graphs of example signals in the high-side switch circuit of FIG. 2 illustrating control of switch closure based on overload severity.

### DETAILED DESCRIPTION

High-side switch circuits can be used to control the provision of power to a load circuit in a variety of applications. If the current drawn from the high-side switch circuit by the load circuit exceeds an overload threshold, then the high-side switch circuit can limit the current flowing to the load circuit to a selected current value. Control of the current flowing to the load circuit may be implemented by changing a control voltage provided to a switching device, such as a field effect transistor (FET). However, reducing the control voltage provided to the switching device increases the power burned by the switching device, which can lead to overheating (a thermal fault).

The high-side switch circuits described herein detect an overload condition, and select a response based on the severity of the overload. If the overload exceeds a severity threshold, then the high-side switch circuit may latch an internal switch open until closed responsive to a signal received from an external controller. If the overload does not exceed the severity threshold, then the high-side switch may temporarily open the internal switch, and automatically reclose the switch after expiration of a retry interval. Accordingly, the high-side switch circuits may provide a response (latching or automatic retry) selected to maintain switch operation while protecting the high-side switch circuit.

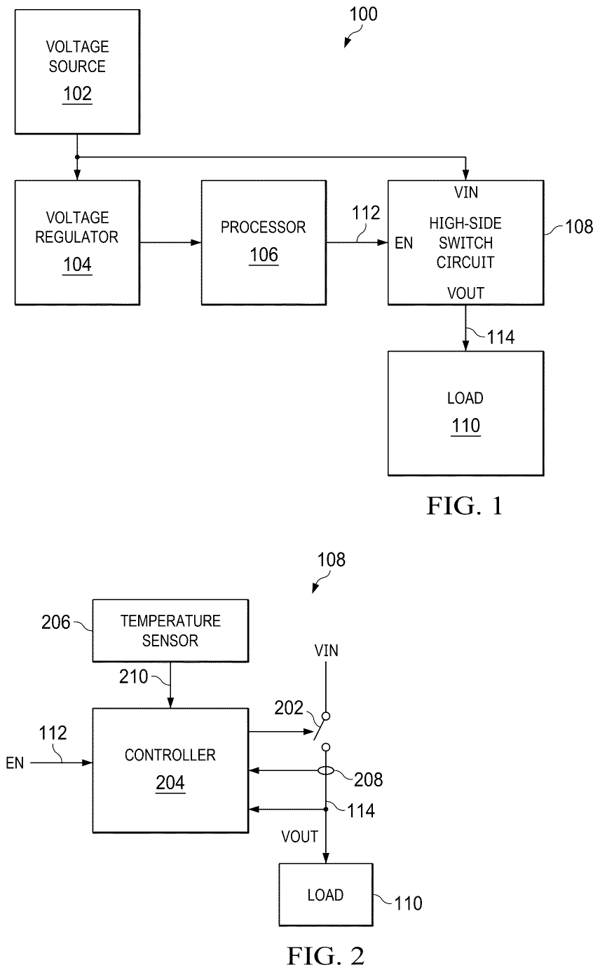

FIG. 1 is a block diagram of an example system 100. The system 100 may be included in a vehicle, such as an automobile, a computer, an industrial system, or any other system that controls power using high-side switching. The system 100 includes a voltage source 102, a voltage regulator 104, a processor 106, a high-side switch circuit 108, and a load circuit 110. The voltage source 102 may be a battery, a battery pack, or other voltage generation device. The voltage source 102 has an output, at which a source voltage is provided. The voltage regulator 104 has an input coupled to the output of the voltage source 102. The voltage regulator 104 converts the source voltage to a regulated voltage suitable for powering the processor 106. For example, the voltage regulator 104 is a step-down converter that converts a relatively high source voltage provided at the output of the voltage source 102 to a lower regulated voltage suitable for powering the processor 106. The voltage regulator 104 has an output at which the regulated voltage is provided.

The processor 106 is powered by the regulated voltage provided by the voltage regulator 104. In one example, the processor 106 is a part of a microcontroller unit (MCU) that controls other operations of the system 100. Where the system 100 is an automobile, the MCU may control operations such as engine control, power steering, airbag deployment, infotainment systems, advanced driver assistance systems (ADAS), etc. The output of the voltage regulator 104 is coupled to an input voltage terminal of the processor 106. The processor 106 generates an enable signal 112 that triggers operation of the high-side switch circuit 108 (e.g., enabling and disabling current flow through the high-side switch circuit 108). The processor 106 has an output at which the enable signal 112 is provided. The output of the processor 106 is coupled to an enable input of the high-side switch circuit 108.

An input voltage terminal (VIN) of the high-side switch circuit 108 is coupled to the output of voltage source 102. The high-side switch circuit 108 switches the source voltage to the load circuit 110 under control of the enable signal 112 received from the processor 106. An output terminal (VOUT) of the high-side switch circuit 108 is coupled to an input voltage terminal of the load circuit 110. The high-side switch circuit 108 provides an output voltage 114 at VOUT for powering the load circuit 110. The load circuit 110 may be any circuit that can be powered by the output voltage 114. For example, in an automotive application, the load circuit 110 may include circuitry of an ADAS, an automotive display module, or a body control module. The high-side switch circuit 108 may enable current flow from VIN to VOUT responsive to the enable signal 112 having a first state (e.g., a logic high), and may disable current flow from VIN to VOUT responsive to the enable signal 112 having a second state (e.g., a logic low state).

The high-side switch circuit 108 detects current flow from VIN to VOUT. If the current flow exceeds a threshold, the high-side switch circuit 108 may reduce the current flow, which causes the temperature of the high-side switch circuit 108 to rise. If the temperature of the high-side switch circuit 108 exceeds a threshold (an overtemperature condition), the high-side switch circuit 108 disables current flow from VIN to VOUT. After disabling current flow, the high-side switch circuit 108 can select a response to the overtemperature condition based on the severity of the overcurrent condition that produced the overtemperature condition. If the overcurrent condition does not exceed a severity threshold, then high-side switch circuit 108 may reenable current flow from VIN to VOUT after expiration of a retry interval. If the overcurrent condition does exceed the severity threshold, then high-side switch circuit 108 may disable current flow from VIN to VOUT until the processor 106 toggles the enable signal. Toggling the enable signal may generally include changing the state of the enable signal from a first state to a second state, and may more particularly include changing the state of the enable signal from the first state to the second state, and back to the first state.

Accordingly, the high-side switch circuit 108 may provide a response (latching or automatic retry) to an overtemperature condition based on overload severity, which reduces management of the high-side switch circuit 108 by the processor 106. Because the high-side switch circuit 108 automatically selects latching or retry operation, the high-side switch circuit 108 may omit an input terminal or non-volatile storage related to selection of latching or retry operation, which may reduce package and/or circuit size. The high-side switch circuit 108 may be part of electronic fuse circuit in some examples.

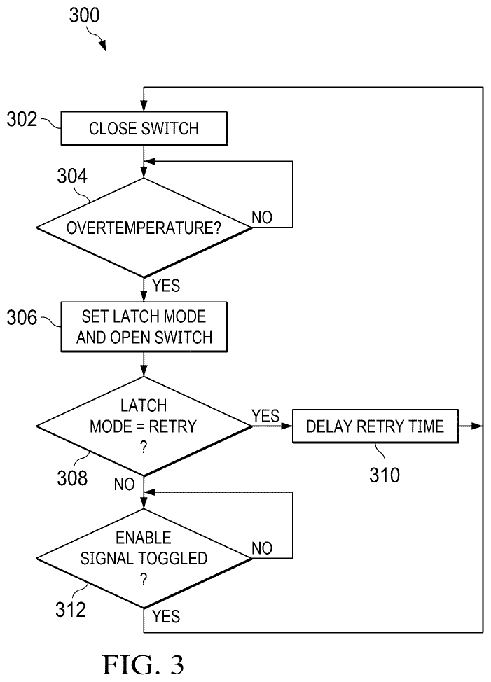

FIG. 2 is a block diagram of an example high-side switch circuit 108 that controls switch closure based on overload severity. The high-side switch circuit 108 includes a switch 202 (also referred to as a switching device), a controller 204, a temperature sensor 206, and a current sensor 208. The switch 202 can be opened or closed to disable or enable current flow from VIN to VOUT. The switch 202 has a first terminal coupled to VIN, a second terminal coupled to VOUT, and a control input (that may also be referred to as a control terminal) coupled to the controller 204.

The controller 204 controls the switch 202. The controller 204 has an output coupled to the control input of the switch 202. The controller 204 provides, at the output of the controller 204, a control signal that enables or disables current flow through the switch 202. The controller 204 has first input coupled to the processor 106 (FIG. 1) for receipt of the enable signal 112. The controller 204 has a second input coupled to the temperature sensor 206. The temperature sensor 206 measures the temperature of the high-side switch circuit 108 (e.g., the temperature of a die including the high-side switch circuit 108). The temperature of the high-side switch circuit 108 may be determined, in large part, by the temperature of the switch 202. The temperature sensor 206 has an output coupled to the second input of the controller 204. The temperature sensor 206 provides, at the output of the temperature sensor 206, a temperature sense signal 210 representing the measured temperature of the high-side switch circuit 108. In some examples, the temperature sense signal 210 is a digital signal that indicates whether the temperature of the high-side switch circuit 108 exceeds a threshold (an overtemperature threshold). If the temperature of the high-side switch circuit 108 is less than the threshold, then the temperature sense signal 210 may have a first state (e.g., a logic low state). If the temperature of the high-side switch circuit 108 is greater than the threshold, then the temperature sense signal 210 may have a second state (e.g., logic high state) indicating an overtemperature condition.

The controller 204 has a third input coupled to the current sensor 208. The current sensor 208 senses the current flowing through the switch 202, and provides a current sense signal representing the measured current to the controller 204. In examples of the high-side switch circuit 108, the current sensor 208 may be coupled to the first or second terminal of the switch 202. The controller 204 may identify an overcurrent condition based on the current sense signal. For example, the controller 204 may include overcurrent circuitry 415. The overcurrent circuitry 415 may include comparators that compare the current sense signal to one or more current limits (e.g., I_{CL}, 2I_{CL}, etc.)to identify an overcurrent condition (an overload). The overcurrent circuitry 415 may also include logic that turn the transistor 402 on or off responsive to detection of an overcurrent condition. Such logic circuitry may include a timer that defines the time (a retry interval) that the transistor 402 is turned off responsive to an overcurrent condition. The logic circuitry may turn the transistor 402 back on responsive to expiration of the retry interval.

The controller 204 has a fourth input coupled to VOUT. In some examples, the controller 204 uses the output voltage 114 provided at VOUT as an indicator of overload severity to determine how to respond to an overtemperature event. If the output voltage 114 provided at VOUT is greater than a reference voltage (e.g., greater than 3 volts) or an inrush interval has not expired, then the controller 204 may respond to an overtemperature condition by opening the switch 202 and reclosing the switch 202 after a retry interval. The inrush interval may be a selected time starting at closure of the switch 202. If the output voltage 114 provided at VOUT is less than the reference voltage and the inrush interval has expired, then the switch 202 may respond to an overtemperature condition by opening the switch 202, and holding the switch 202 open until the enable signal 112 is toggled.

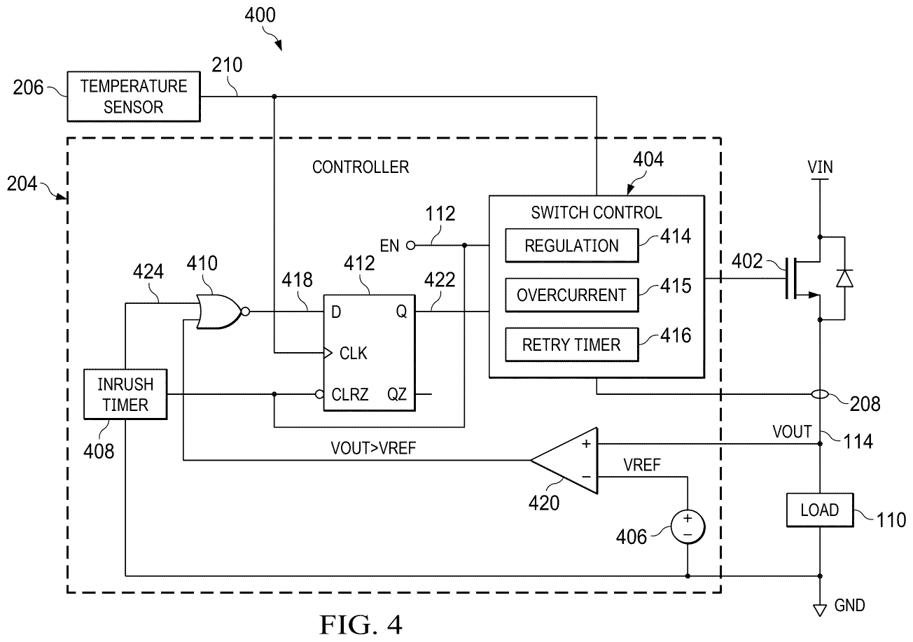

FIG. 3 is a flow diagram of an example method 300 of controlling switch closure in a high-side switch circuit based on overload severity. Though depicted sequentially as a matter of convenience, at least some of the actions shown can be performed in a different order and/or performed in parallel. Additionally, some implementations may perform only some of the actions shown. Operations of the method 300 may be performed by an example of the high-side switch circuit 108.

In block 302, the enable signal 112 changes state from a logic low state to a logic high state to initiate closure of the switch 202. The enable signal 112 may be provided by a circuit (such as the processor 106) that is external to the high-side switch circuit 108. In response to the enable signal 112, the controller 204 generates a control signal that causes the switch 202 to close.

In block 304, the controller 204 determines whether an overtemperature condition has been detected. An overtemperature condition may be detected by the temperature sensor 206. The temperature sensor 206 measures the temperature of the high-side switch circuit 108, and provides a temperature sense signal 210 indicating that an overtemperature condition is present if the temperature of the high-side switch circuit 108 exceeds a threshold.

If an overtemperature condition is detected, then, in block 306, the controller 204 sets a latch mode and generates a control signal that causes the switch 202 to open. The latch mode indicates how the controller 204 is to respond to the overtemperature condition after opening the switch 202. The controller 204 may set the latch mode based on the output voltage 114 exceeding a threshold, where the relationship of the output voltage 114 to the threshold is indicative of the severity of the overload causing the overtemperature condition. If the output voltage 114 exceeds the threshold, then the overload may be less severe, and the latch mode may be set to retry. If the output voltage 114 is below the threshold, then the overload may be more severe, and the latch mode may be set to latch.

In block 308, if the latch mode is set to retry, then the controller 204 delays for a retry time interval in block 310, and recloses the switch 202 in block 302. The retry time interval may include sufficient time for the temperature of the high-side switch circuit 108 to drop below the overtemperature threshold.

In block, 308, if the latch mode is not set to retry (e.g., the latch mode is set to latch), then, in block 312, the controller 204 holds the switch 202 open until the enable signal 112 is toggled. When the enable signal 112 is toggled, the controller 204 closes the switch 202 in block 302.

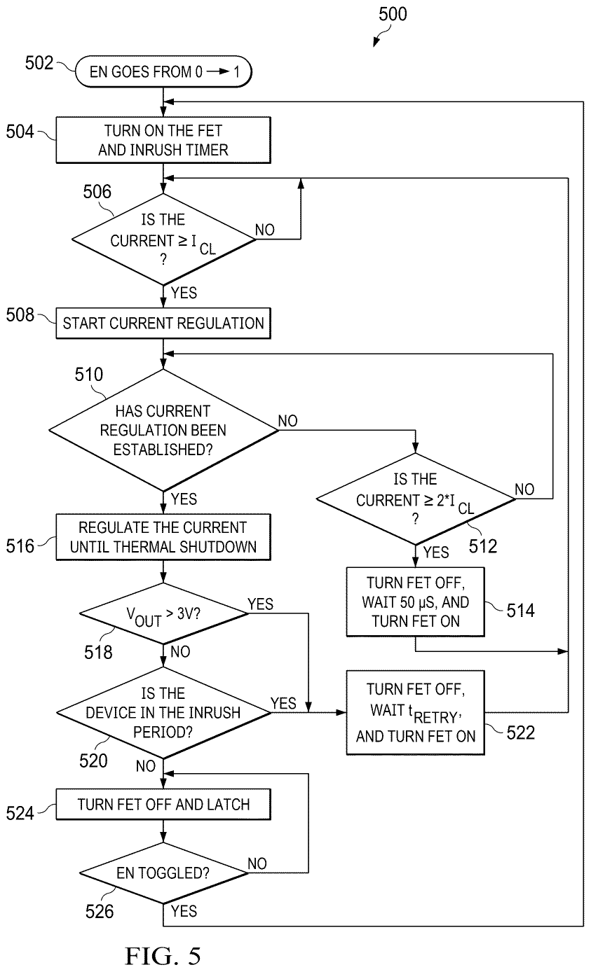

FIG. 4 is a schematic diagram of an example high-side switch circuit 400. The high-side switch circuit 400 is an example of the high-side switch circuit 108. The high-side switch circuit 400 includes the controller 204, the temperature sensor 206, the current sensor 208, and a transistor 402. The transistor 402 is a switching device that implements the switch 202. The transistor 402 operates as pass transistor to conduct current between VIN and VOUT. The transistor 402 may be an n-channel metal oxide semiconductor field effect transistor (NFET). The transistor 402 has a first terminal (e.g., drain) coupled to VIN. The transistor 402 has a second terminal (e.g., source) coupled to VOUT. The transistor 402 has a control terminal (e.g., gate) coupled to the output of the controller 204. The current sensor 208 is coupled to the second terminal of the transistor 402, and may be implemented using a sense transistor or a sense resistor in various examples. In examples of the high-side switch circuit 400, the current sensor 208 may be coupled to the first or second terminal of the transistor 402.

The controller 204 includes a switch control circuit 404. The switch control circuit 404 provides the control signal that turns the transistor 402 on or off (e.g., opens or closes the switch 202 as described with regard to the high-side switch circuit 108). The switch control circuit 404 includes a regulation circuit 414, and a retry timer 416. The regulation circuit 414 sets the voltage of the control signal to regulate the current flowing through the transistor 402. For example, if the sense signal provided by the current sensor 208 indicates that the current flowing through the transistor 402 exceeds a threshold, then the regulation circuit 414 may reduce the voltage of the control signal to reduce the current flowing through the transistor 402.

The retry timer 416 defines a retry time interval for turning the transistor 402 on after the transistor 402 has been turned off due to an overtemperature condition. In some examples of the switch control circuit 404, the retry interval may be variable. For example, the retry interval may include an overtemperature interval defined by the temperature sense signal 210 so that the transistor 402 remains off until the temperature of the high-side switch circuit 400 is below the overtemperature threshold. Accordingly, some examples of the switch control circuit 404 include an input coupled to the output of the temperature sensor 206 for receipt of the temperature sense signal 210.

The controller 204 determines, based on overload severity, whether the switch control circuit 404 should retry turn-on of the transistor 402 or latch the transistor 402 off in response to an overtemperature condition. The controller 204 also includes a comparator 420, a voltage reference circuit 406, an inrush timer 408, a logic gate 410, and a flip-flop 412. The comparator 420 compares the output voltage 114 at VOUT to a reference voltage (VREF) provided by the voltage reference circuit 406. The comparator 420 has a first input (e.g., a non-inverting input) coupled to VOUT for receipt of the output voltage 114. The comparator 420 has a second input (e.g., an inverting input) coupled to an output of the voltage reference circuit 406 for receipt of VREF. The comparator 420 has an output, at which an output signal VOUT>VREF is provided. VOUT>VREF is an indicator of overload severity. VOUT>VREF may have a first state (e.g., a logic high state), indicating an overload is less severe, if the output voltage 114 is greater than VREF. VOUT>VREF may have a second state (e.g., a logic low state), indicating an overload is more severe, if the output voltage 114 is less than VREF.

The inrush timer 408 times an interval from turn on of the transistor 402 (e.g., an inrush interval starting at a transition of the enable signal 112 to a first logic state). The inrush timer 408 has an input coupled to EN for receipt of the enable signal 112. The inrush timer 408 has an output at which an inrush time signal 424 is provided. The inrush signal may have a first state (e.g., a logic high state) between turn-on of the transistor 402 and the end of the inrush interval. The inrush time signal 424 may have a second state (e.g., a logic low state) after the end of the inrush interval. The inrush timer 408 may be reset responsive to the enable signal having a second state, or responsive to a transition of the enable signal to the first state. The inrush interval defines a time during which capacitors of the load circuit 110 may be charged after the transistor 402 has been turned on, and during which the current flow through the transistor 402 may be relatively high.

The logic gate 410 has a first input coupled to the output of the inrush timer 408. The logic gate 410 has a second input coupled to the output of the comparator 420. The logic gate 410 has an output, at which a latch signal 418 is provided. The logic gate 410 combines the inrush signal and VOUT>VREF to produce the latch signal 418. The latch signal 418 may have a first state (e.g., a logic low state) during the inrush interval or if VOUT>VREF has a logic high state. The latch signal 418 may have a second state (e.g., a logic high state) after the inrush interval if VOUT>VREF has a logic low state.

The flip-flop 412 stores the state of the latch signal 418 provided by the logic gate 410 responsive to the temperature sense signal 210 provided by the temperature sensor 206. The flip-flop 412 has a data input (D) coupled to the output of the logic gate 410 for receipt of the latch signal 418. The flip-flop 412 has a clock input (CLK) coupled to the output of the temperature sensor 206. The flip-flop 412 has a reset input (CLRZ) coupled to EN for receipt of the enable signal 112. The flip-flop 412 has an output (Q) at which the latch mode signal 422 is provided. The output of the flip-flop 412 is coupled to a first input of the switch control circuit 404.

If the enable signal 112 has a logic low state, the flip-flop 412 sets the latch mode signal 422 to a state indicating that the switch control circuit 404 should retry turn-on of the transistor 402. If the enable signal 112 has a logic high state, then the flip-flop 412 stores the state of the latch signal 418 responsive to a transition (e.g., a rising edge) of the temperature sense signal 210, and sets the state of the latch mode signal 422 to the state of the latch signal 418. Accordingly, the latch mode signal 422 indicates that the transistor 402 should be latched off responsive to an overtemperature condition (which will be caused by an overcurrent condition) if the inrush interval has expired and the output voltage 114 is less than VREF. During the inrush interval, or if the output voltage 114 is greater than VREF, the latch mode signal 422 indicates that turn-on of the transistor 402 should be retried.

Accordingly, the controller 204 indicates, via the latch mode signal 422, that the switch control circuit 404 should retry turn on of the transistor 402 during the inrush interval (when an overcurrent condition may be caused by charging capacitors of the load circuit 110) or if the severity of the overload is relatively low. After expiration of the inrush interval, if the severity of the overload is relatively high, the controller 204 indicates, via the latch mode signal 422, that the switch control circuit 404 should latch the transistor 402 off until the enable signal 112 toggles. The controller 204 changes the state of the latch mode signal 422 responsive to the temperature sense signal 210.

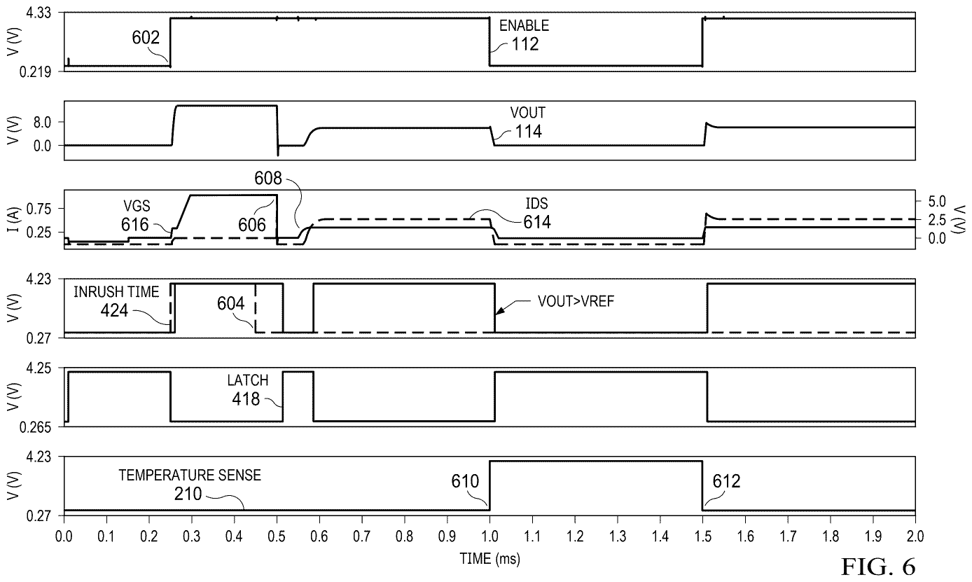

FIG. 5 is a flow diagram of an example method 500 of controlling switch closure in a high-side switch circuit based on overload severity. Though depicted sequentially as a matter of convenience, at least some of the actions shown can be performed in a different order and/or performed in parallel. Additionally, some implementations may perform only some of the actions shown. Operations of the method 500 may be performed by an example of the high-side switch circuit 400.

In block 502, the enable signal 112 changes state from a logic low state to a logic high state to initiate turn on of the transistor 402. The enable signal 112 may be provided by a circuit (such as the processor 106) that is external to the high-side switch circuit 400.

In block 504, the controller 204 turns on the transistor 402. The inrush timer 408 initiates timing of the inrush interval responsive to the enable signal 112 changing state in block 502.

In block 506, the controller 204 determines whether the current flowing through transistor 402 exceeds a current limit (I_{CL}) (the controller 204 tests for an overcurrent condition) based on the current sense signal received from the current sensor 208. If the current does not exceed the threshold, then the controller 204 continues to monitor the current in block 506.

If the current flowing through the transistor 402 exceeds the current limit in block 506, then the controller 204 initiates current regulation in block 508. The controller 204 (via the regulation circuit 414) may adjust (e.g., reduce) the control voltage provided to the transistor 402 to regulate the current flowing through the transistor 402.

In block 510, the controller 204 determines whether the current flowing through transistor 402 has been regulated (e.g., the current has been reduced to less than the threshold). If the current has not been regulated, then the controller 204 compares the current flowing through the transistor 402 to a second threshold (e.g., 2I_{CL}). If the current flowing through the transistor 402 does not exceed the second threshold, then the method returns to block 508 to check for regulation.

If the current flowing through the transistor 402 exceeds the second threshold in block 512, then the controller 204 turns off the transistor 402 in block 514. After turning off the transistor 402, the controller 204 may wait a selected time (e.g., 50 microseconds), turn the transistor 402 back on, and return to block 506 to test for overload.

Regulation of the current flowing through the transistor 402 causes the voltage across the transistor 402 (drain-to-source voltage) to increase, which increases the power dissipated by the transistor 402 and causes a rise in temperature. If the current flowing through the transistor 402 has been regulated in block 510, then, in block 516, the controller 204 continues to regulate the current until the temperature sense signal 210 provided by the temperature sensor 206 indicates that the temperature of the high-side switch circuit 400 exceeds a threshold (e.g., an overtemperature condition is present).

In block 518, the controller 204 determines whether the output voltage 114 provided at VOUT exceeds a threshold defined by VREF(e.g., 3 volts). If the output voltage 114 exceeds the threshold, then the controller 204 turns off the transistor 402 in block 522, and starts the retry timer 416. The controller 204 may turn the transistor 402 back on when the retry interval expires, and return to block 506 to continue the method 500.

If the output voltage 114 provided at VOUT does not exceed the threshold in block 518, then the controller 204 determines whether the inrush interval has expired in block 520. If the inrush interval has not expired, then the controller 204 turns off the transistor 402 in block 522, and starts the retry timer 416. The controller 204 may turn the transistor 402 back on when the retry interval expires, and return to block 506 to continue the method 500. Accordingly, during the inrush interval, when capacitance of the load circuit 110 is being charged and drawing relatively high currents, the high-side switch circuit 400 can turn the transistor 402 off and back on (retry) without external intervention.

If, in block 520, the inrush interval has expired when an overtemperature condition has been detected (in block 516), then the controller 204 turns off the transistor 402, and latches (holds) the transistor 402 off in block 524 until the enable signal 112 is toggled in block 526. If the enable signal 112 is toggled, in block 526, then the method 500 continues in block 504.

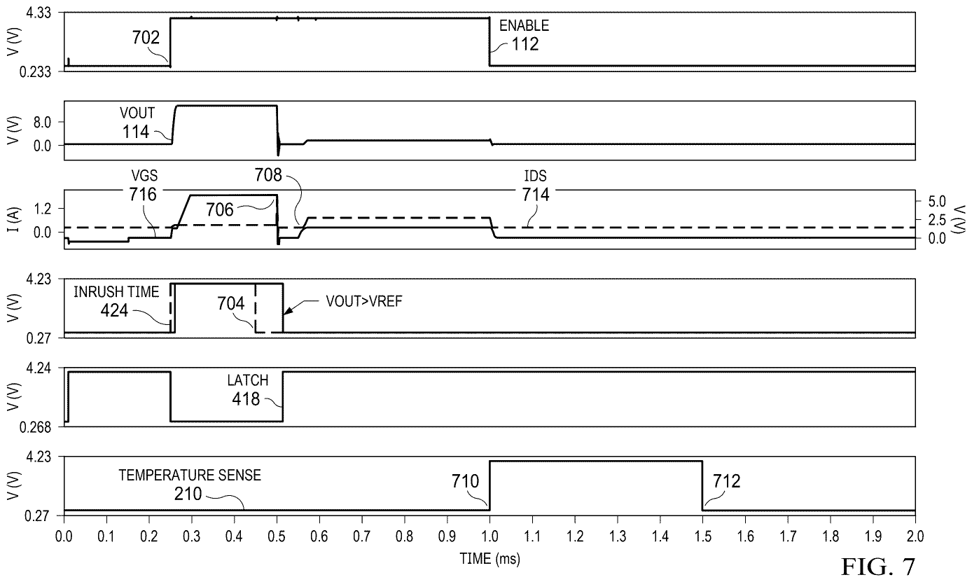

FIGS. 6 and 7 are graphs of example signals in the high-side switch circuit 400 illustrating control based on overload severity. FIGS. 6 and 7 show the enable signal 112, output voltage 114, current 614 through the transistor 402, the gate-source voltage 616 of the transistor 402, VOUT>VREF, inrush time signal 424, latch signal 418, and the temperature sense signal 210. FIG. 6 shows retry operation responsive to less severe overloads. At time 602, the enable signal 112 transitions, and the controller 204 turns on the transistor 402 (VGS rises) and starts the inrush timer 408. The output voltage 114 rises to about 13.5 volts at about 135 milliamperes of current. The inrush time signal 424 is a logic high during the inrush interval. The latch signal 418 is a logic low if the inrush signal is a logic high or the output voltage 114 exceeds the threshold voltage (e.g., 3 volts). At time 604, the inrush interval expires and the inrush time signal 424 transitions from logic high to logic low.

At time 606, the load resistance decreases, and the current through the transistor 402 increases to about 1 ampere. This current exceeds the current limit of the high-side switch circuit 400. The high-side switch circuit 400 senses the overcurrent condition, turns off the transistor 402, and the output voltage 114 falls to zero. VOUT>VREF transitions from logic high to logic low responsive to the reduction in output voltage 114.

At time 608, the controller 204 turns the transistor 402 on with a reduced gate voltage to limit the current flowing through the transistor 402, and the output voltage 114 rises to about 6 volts. Responsive to the increase in output voltage 114, VOUT>VREF transitions for logic low to logic high. The temperature of the high-side switch circuit 400 increases responsive to current flow through the transistor 402, and at time 610, the temperature of the high-side switch circuit 400 exceeds an overtemperature threshold. The temperature sense signal 210 transitions from logic low to logic high to indicate the overtemperature condition. At time 610, the output voltage 114 exceeds the reference voltage (e.g., the output voltage 116 is greater than 3 volts), and the inrush interval has expired. Accordingly, the latch signal 418 is logic low, the controller 204 sets the latch mode to retry, and the controller 204 turns the transistor 402 off.

At time 612, the temperature of the high-side switch circuit 400 has fallen below the overtemperature threshold. The controller 204 is set for retry, and the controller 204 turns the transistor 402 back on. The output voltage 114 again rises to about 6 volts. Accordingly, the high-side switch circuit 400 operates in retry mode if the output voltage 114 of the high-side switch circuit 400 indicates the presence of a relatively low severity overload.

FIG. 7 shows latching operation responsive to more severe overloads. At time 702, the enable signal 112 transitions and the controller 204 turns on the transistor 402 (gate-to-source voltage 716 rises) and starts the inrush timer 408. The output voltage 114 rises to about 13.5 volts at about 135 milliamperes of current 714. The inrush time signal 424 is a logic high during the inrush interval. The latch signal 418 is logic low if the inrush signal is a logic high or the output voltage 114 exceeds the threshold voltage (e.g., 3 volts). At time 704, the inrush interval expires and the inrush time signal 424 transitions from logic high to logic low.

At time 706, the load resistance decreases, and the current 714 through the transistor 402 increases to about 1.76 amperes. This current 714 exceeds the current limit of the high-side switch circuit 400. The high-side switch circuit 400 senses the overcurrent condition, turns off the transistor 402, and the output voltage 116 falls to zero. VOUT>VREF transitions from logic high to logic low responsive to the reduction in output voltage 114.

At time 708, the controller 204 turns on the transistor 402 with a reduced gate-to-source voltage 716 to limit the current 714 flowing through the transistor 402, and the output voltage 114 rises to about 1.36 volts. The output voltage 114 is less than the reference voltage (VREF) provided by the voltage reference circuit 406, and VOUT>VREF remains logic low. The temperature of the high-side switch circuit 400 increases responsive to current flow through the transistor 402, and at time 710, the temperature of the high-side switch circuit 400 exceeds an overtemperature threshold. The temperature sense signal 210 transitions from logic low to logic high to indicate the overtemperature condition. With VOUT>VREF logic low, and the inrush signal logic low, the controller 204 latches the transistor 402 off until the enable signal 112 transitions from a logic low to a logic high. Accordingly, after the temperature sense signal 210 transitions from logic high to logic low at time 712, the transistor 402 remains turned off pending toggling of the enable signal.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET) ) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a transistor having a first terminal, a second terminal, and a control terminal; and
a controller having an output coupled to the control terminal of the transistor, and an input coupled to the second terminal of the transistor, the controller capable of:
turning the transistor on responsive to an enable signal;
comparing a voltage at the input of the controller to a threshold; and
responsive to a result of the comparing, either latching the transistor off or turning the transistor off for a time and then turning the transistor back on.

2. The apparatus of claim 1, wherein the controller is capable of latching the transistor off responsive to the voltage being less than the threshold.

3. The apparatus of claim 1, wherein the controller is capable of turning the transistor off for the time and then turning the transistor back on responsive to the voltage exceeding the threshold.

4. The apparatus of claim 1, wherein:
the input is a first input;
the controller has a second input; and
the controller includes a timer capable of timing an inrush interval; and the controller is capable of:
responsive to the inrush interval not having expired:
delaying a selected time; and
providing a control signal at the output of the controller, the control signal having a first state selected to turn on the transistor; and
responsive to the inrush interval having expired:
providing the control signal having a second state selected to turn off the transistor until an enable signal received at the second input of the controller is toggled; and
responsive to the enable signal being toggled, providing the control signal having the first state selected to turn on the transistor.

5. The apparatus of claim 4, wherein the controller is capable of starting the timer responsive to a transition of the enable signal.

6. The apparatus of claim 4, further comprising:
a temperature sensor having an output, the temperature sensor capable of providing a temperature sense signal at the output of the temperature sensor;
wherein the controller has a third input coupled to the output of the temperature sensor; and the controller is capable of providing the control signal having the second state selected to turn off the transistor responsive to the temperature sense signal indicating an overtemperature condition.

7. The apparatus of claim 6, wherein the controller includes:
a voltage reference circuit having an output;
a comparator having a first input coupled to the second terminal of the transistor, a second input coupled to the output of the voltage reference circuit, and an output;
a logic gate having a first input coupled to the output of the comparator, a second input coupled to the output of the timer, and an output; and
a flip-flop having a data input coupled to the output of the logic gate, a clock input coupled to the output of the temperature sensor, and an output, a mode signal provided at the output of the flip-flop has a first state indicating retry operation and a second state indicating latch operation.

8. A circuit comprising:
a switch having a control input and a terminal;
temperature sensor circuitry having an output;
a comparator having a first input coupled to the terminal of the switch, a reference input, and an output;
logic circuitry having an input coupled to the output of the comparator, and an output; and
a switch control circuit having a first input coupled to the output of the temperature sensor circuitry, a second input coupled to the output of the logic circuitry, and an output coupled to the control input of the switch.

9. The circuit of claim 8 wherein:
the input of the logic circuitry is a first input;
the logic circuitry has a second input; and
the circuit includes a timer having an output coupled to the second input of the logic circuitry.

10. The circuit of claim 9, wherein the logic circuitry includes a logic gate having a first input coupled to the output of comparator, a second input coupled to the output of the timer, and an output.

11. The circuit of claim 10, wherein the logic circuitry includes a flip-flop having a data input coupled to the output of the logic gate, a clock input coupled to the output of the temperature sensor circuitry, and an output coupled to the second input of the switch control circuit.

12. The circuit of claim 11, wherein:
the temperature sensor circuitry is capable of detecting an overtemperature condition;
the comparator is capable of comparing an output voltage provided by the switch to a threshold;
the switch control circuit is capable of:
opening the switch responsive to the overtemperature condition; and
after opening the switch, closing the switch responsive to the output voltage exceeding the threshold.

13. The circuit of claim 12, further comprising an inrush timer capable of timing an inrush interval starting at closure of the switch;
wherein:
the logic circuitry is capable of determining whether the inrush interval has expired responsive to opening the switch;
the switch control circuit is capable of:
closing the switch responsive to the inrush interval not having expired and expiration of a retry interval after opening the switch; and
closing the switch responsive to the inrush interval having expired, the output voltage not exceeding the threshold, and receipt of an enable signal.

14. The circuit of claim 12, wherein the temperature sensor circuitry is capable of:
measuring a temperature of the switch; and
comparing the temperature to an overtemperature threshold; and
providing a temperature sense signal indicating that the temperature exceeds the overtemperature threshold.

15. A system comprising:
a battery having a terminal;
a load circuit having an input;
a processor having an output; and
a switch circuit including:
a temperature sensor having an output;
a transistor having a first terminal coupled to the terminal of the battery, a second terminal coupled to the input of the load circuit, and a control terminal;
a controller including:
a comparator having a first input coupled to the second terminal of the transistor, a second input, and an output, the comparator capable of providing an output signal responsive to comparing a voltage at its input to a reference voltage at its second input;
circuitry having a first input coupled to the output of the processor, a second input coupled to the output of the comparator, and an output coupled to the control terminal of the transistor, the circuitry of the controller capable of:
turning on the transistor responsive to a first enable signal at the output of the processor;
turning off the transistor responsive to a signal at the output of the temperature sensor; and
either latching the transistor off or turning the transistor off for a time and turning the transistor back on responsive the output signal from the comparator.

16. The system of claim 15, wherein:
the controller has a third input; and
the controller is capable of:
turning off the transistor until an enable signal received at the third input of the controller is toggled; and
responsive to the enable signal being toggled, turning on the transistor.

17. The system of claim 15, wherein the controller includes a timer having an output, the timer capable of timing an inrush interval; and the controller is capable of, responsive to the inrush interval not having expired:
delaying a selected time; and
turning on the transistor.

18. The system of claim 17, wherein the controller is capable of:
responsive to the inrush interval having expired, turning off the transistor until an enable signal received at the second input of the controller is toggled; and
responsive to the enable signal being toggled, turning on the transistor.

19. The system of claim 18, wherein the controller is capable of starting the timer responsive to a transition of the enable signal.

20. The system of claim 17, wherein the circuitry includes:
a logic gate having a first input coupled to the output of the comparator, a second input coupled to the output of the timer, and an output; and
a flip-flop having a data input coupled to the output of the logic gate, a clock input coupled to the output of the temperature sensor, and an output, a mode signal provided at the output of the flip-flop has a first state indicating retry operation and a second state indicating latch operation.
